(19) United States
(12) Patent Application Publication
(10) Pub. No.: US 2014/0202516 A1
(43) Pub. Date: Jul. 24, 2014

(54) SOLAR CELL, SOLAR CELL MODULE, AND METHOD FOR MANUFACTURING SOLAR CELL

(71) Applicant: SANYO Electric Co., Ltd., Osaka (JP)

(72) Inventor: Satoshi TOHODA, Osaka (JP)

(73) Assignee: SANYO Electric Co., Ltd., Osaka (JP)

(21) Appl. No.: 14/218,185

(22) Filed: Mar. 18, 2014

Related U.S. Application Data
(63) Continuation of application No. PCT/JP2011/072312, filed on Sep. 29, 2011.

(51) Int. Cl. H01L 31/05; H01L 31/02

(52) U.S. Cl. CPC H01L 31/0504; H01L 31/02013
USPC 136/244; 136/256; 438/98

(57) ABSTRACT

A solar cell is provided with current collecting finger portions, which are formed on the light receiving surface of a photoelectric conversion unit. A separation region is provided on the light receiving surface to extend in the direction that intersects the current collecting finger portions such that the current collecting finger portions are separated from each other, and the current collecting finger portions positioned on both the sides with the separation region therebetween are electrically separated from each other.

### CROSS-REFERENCE TO RELATED APPLICATION

The present application is a continuation under 35 U.S.C. §120 of PCT/JP2011/072312, filed Sep. 29, 2011, which is incorporated herein by reference.

### TECHNICAL FIELD

The present invention relates to a solar cell, a solar cell module, and a method for manufacturing the solar cell.

### BACKGROUND ART

A solar cell has a photoelectric conversion unit and an electrode formed on a main surface of the photoelectric conversion unit (see, for example, Patent Document 1). The electrode includes fine-line finger portions. Patent document 1 discloses a structure in which finger portions having different widths are combined.

### CITATION LIST

### Patent Document

Patent Document 1: Japanese Registered Utility Model No. 3154145

In order to modularize the solar cell, wiring members for electrically connecting a plurality of solar cells to each other are attached to the finger portions. Although the wiring members are thermally compressed onto the finger portion using, for example, an adhesive, typically, there are irregularities on the finger portion, and thus a convex portion contacts the wiring member to thereby function as a collecting point. However, because these irregularities exist at random, the collecting points occur randomly, and this may cause a longer current path and thus output loss.

### SUMMARY

A solar cell according the present invention has current collecting finger portions formed on a main surface of a photoelectric conversion unit, and in this solar cell a separation region is formed on the main surface so as to extend in a direction intersecting with the current collecting finger portions to thereby separate the current collecting finger portions, and the current collecting finger portions arranged on both sides of the separation region with the separation region therebetween are electrically separated from each other.

A solar cell module according to the present invention has a plurality of the solar cells and a wiring member for connecting the solar cells, and in this module, the wiring member is provided so as to extend across ends of current collecting finger portions arranged on both sides of the separation region with the separation region therebetween.

A method of manufacturing a solar cell according to the present invention has the step of forming current collecting finger portions on a main surface of a photoelectric conversion unit by screen printing, and in this step, the current collecting finger portions are formed while a separation region extending in a direction intersecting with the current collecting finger portions to separate the current collecting finger portions remains on the main surface, and the current collecting finger portions arranged on both sides of the separation region with the separation region therebetween are electrically separated.

With the present invention, it is possible to increase output of the solar cell.

### BRIEF DESCRIPTION OF THE DRAWINGS

FIG. 1 shows a plane view of a solar cell which is an embodiment according to the present invention viewed from a light receiving surface side, in which a position of a wiring member is indicated by a two-dot chain line;

FIG. 2 shows a schematic cross sectional view taken along A-A in FIG. 1;

FIG. 3 shows a schematic cross sectional view of a solar cell module which is an embodiment according to the present invention;

FIG. 4 shows an enlarged view of Part B in FIG. 1;

FIG. 5 shows an enlarged view of Part B in FIG. 1, in which a position of the wiring member is indicated by the two-dot chain line;

FIG. 6 shows an enlarged view of Part C in FIG. 2;

FIG. 7 shows a graph illustrating a relationship between the electrode height and the screen print opening width;

FIG. 8 shows a schematic cross sectional view of a neighborhood of a bus bar portion of a light receiving surface electrode in the solar cell module which is the embodiment according to the present invention;

FIG. 9 shows a variant of the solar cell which is an embodiment according to the present invention; and

FIG. 10 shows a variant of the solar cell which is an embodiment according to the present invention, in which a position of the wiring member is indicated by the two-dot chain line.

### DESCRIPTION OF EMBODIMENTS

The embodiment of the present invention, that is, a solar cell 10, will be described in detail by reference to the drawings. The present invention is not limited to the below-described embodiment. In addition, because the figures referred to in the embodiment are drawn schematically, the size and the ratio of the components drawn in the figures may differ from those of actual components. The specific size and ratio should be decided in consideration of the following description.

In the present embodiment, the direction in which semiconductor layers and electrodes are layered in the photoelectric conversion unit will be referred to as the “thickness direction”.

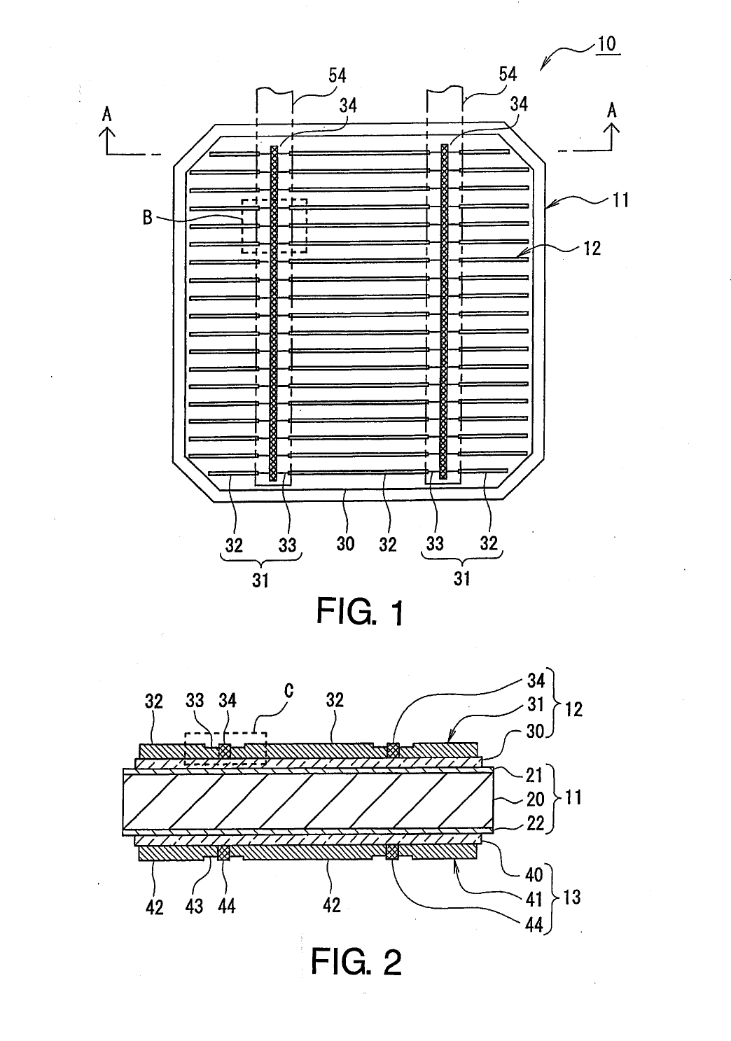

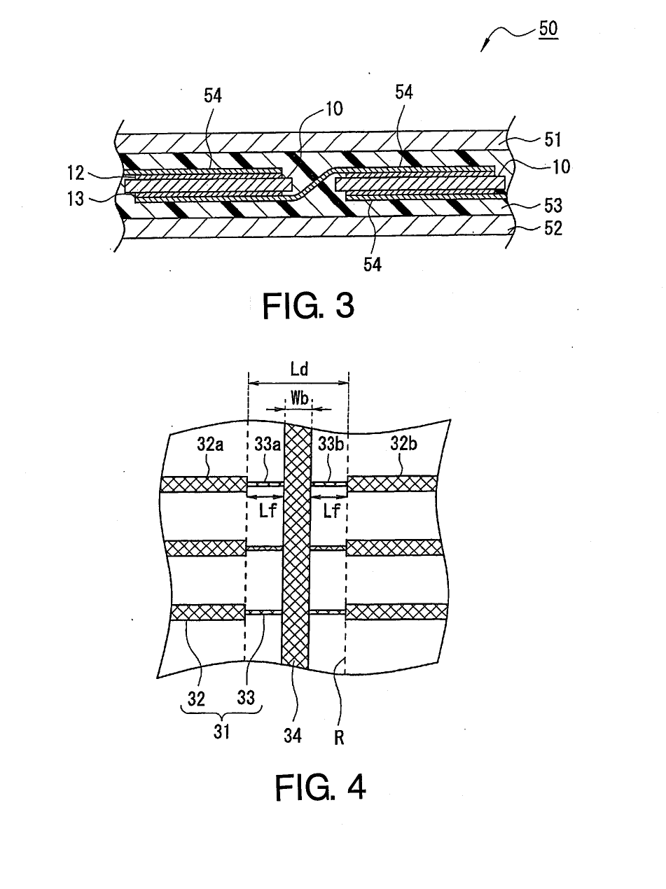

The structure of the solar cell 10 will be described in detail by reference to FIG. 1 and FIG. 2. The structure of a solar cell module 50 having a plurality of solar cells 10 will also be described in detail. FIG. 1 shows a plane view of the solar cell 10 viewed from the light receiving surface side. FIG. 2 shows a cross sectional view taken along A-A in FIG. 1, in which the solar cell 10 cut in the thickness direction along the longitudinal direction of finger portions 31. FIG. 3 shows a cross sectional view of the solar cell module 50. In FIG. 1, the position of a wiring member 54 is indicated by the two-dot chain line.

The solar cell 10 has a photoelectric conversion unit 11 which generates carriers (electrons and electron holes) by receiving solar light, a light receiving surface electrode 12 formed on a light receiving surface of the photoelectric conversion unit 11, and a back surface electrode 13 formed on the back surface of the photoelectric conversion unit 11. In the solar cell 10, the carriers generated in the photoelectric conversion unit 11 are collected by the light receiving surface electrode 12 and the back surface electrode 13. The solar cell 10 has current collecting finger portions 32 and 42 to which the wiring members 54 are connected during modularization. In the present embodiment, the solar cell 10 further has connecting finger portions 33 and 43, and these finger portions will be collectively referred to as finger portions 31 and 41 for explanation.

Here, the “light receiving surface” means a main surface onto which solar light is mainly incident from outside the solar cell 10. For example, 50% to 100% of solar light entering the solar cell 10 enters from the light receiving surface side. The “back surface” means a main surface on the opposite side of the light receiving surface. The surfaces which are provided along the thickness direction of the solar cell 10 and are vertical to the main surface are side surfaces.

The photoelectric conversion unit 11 has, for example, a semiconductor substrate 20, an amorphous semiconductor layer 21 formed on the light receiving surface side of the substrate 20, and an amorphous semiconductor layer 22 formed on the back surface side of the substrate 20. The amorphous semiconductor layers 21 and 22 are formed so as to cover the entire areas of the light receiving surface and the back surface, respectively (including when the entire area is considered to be substantially covered, such as, for example, 95% of the light receiving surface is covered. The same shall apply hereafter).

A specific example of the substrate 20 includes an n-type single crystal silicon substrate. The amorphous semiconductor layer 21 has a layered structure in which, for example, an i-type amorphous silicon layer and a p-type amorphous silicon layer are formed sequentially. The amorphous semiconductor layer 22 has a layered structure in which, for example, an i-type amorphous silicon layer and an n-type amorphous silicon layer are formed sequentially. The photoelectric conversion unit 11 may have a structure in which an i-type amorphous silicon layer and an n-type amorphous silicon layer are sequentially formed on the light receiving surface of the n-type single crystal silicon substrate, while an i-type amorphous silicon layer and a p-type amorphous silicon layer are sequentially formed on the back surface of the n-type single crystal silicon substrate. The photoelectric conversion units 11 can be formed by known methods.

It is preferable to form a texture structure on the light receiving surface and the back surface of the substrate 20. The texture structure is an irregular surface structure for suppressing surface reflectance and increasing light absorption amount by the photoelectric conversion unit 11. The irregularity height of the texture structure is approximately 1 μm to 15 μm. Because the thicknesses of the amorphous semiconductor layers 21 and 22 and transparent conductive layer 30 and 40 are several nm to several tens nm, the irregularity of the texture structure also appears on the transparent conductive layer 30 and 40. The texture structure may also affect the surface shape of the finger units 31 and 41.

The light receiving surface electrode 12 preferably includes the transparent conductive layer 30 formed on the light receiving surface of the photoelectric conversion unit 11. A transparent conductive oxide (TCO) obtained by doping metal oxide, such as indium oxide (In₂O₃) and zinc oxide (ZnO), with tin (Sn) or antimony (Sb) can be adopted as the transparent conductive layer 30. The transparent conductive layer 30 can be formed by sputtering. Although the transparent conductive layer 30 may be formed on the entire area of the amorphous semiconductor layer 21, in the embodiment shown in FIG. 1, it is formed over the entire area of the amorphous semiconductor layer 21, excluding an edge portion thereof.

Further, the light receiving surface electrode 12 preferably includes a plurality of (for example, 50) finger portions 31 formed on the transparent conductive layer 30 and a plurality of (for example, two) bus bar portions 34 formed on the transparent conductive layer 30 so as to extend in the direction intersecting with the finger portion 31. The finger portions 31 are fine-line electrodes formed on a broad area of the transparent conductive layer 30. The bus bars 34 are electrodes which are smaller in number than the finger portions 31 and collect carriers from the finger portions 31.

In the present embodiment, two bus bar portions 34 are arranged in parallel to each other with a predetermined interval therebetween, and the plurality of finger portions 31 are arranged orthogonal to them (including when the finger portions 31 can be regarded as substantially orthogonal to the two bas bars 34, such as when the angle between the finger portions 31 and the bus bar portions 34 is 90°±5°. The same shall apply hereafter).

Like the light receiving surface electrode 12, the back surface electrode 13 preferably includes a transparent conductive electrode 40, a plurality of finger portions 41, and a plurality of bus bar portions 44. However, because, compared to the finger portions 31 on the light receiving surface side, the finger portions 41 are less affected by shadow loss, it is preferable to install more finger portions 41 than the finger portions 31 with narrower intervals (for example, 250 finger portions 41 with an interval of 0.5 mm). In other words, the main surface on which more finger portions are formed is the back surface. If light receiving loss from the back surface side is not a problem, a metal film, such as a silver (Ag) film, may be formed on the approximately entire area of the back surface of the photoelectric conversion unit 11, instead of the finger portions 41.

Although the finger portions 31 and 41 and the bus bar portions 34 and 44 can be formed by plating or sputtering, they are preferably formed by screen printing in terms of productivity, etc. In the screen printing, after a conductive paste (for example, a silver paste) is screen printed on the transparent conductive layer 30 in a desired pattern, a solvent contained in the paste is allowed to volatilize, and the finger portions 31 and the bus bar portions 34 are formed. The conductive paste may include, for example, a binder resin such as an epoxy resin, conductive fillers such as silver and carbon dispersed in the binder resin, and a solvent such as butyl carbitol acetate (BCA). That is, the finger portions 31 and 34 and the bus bar portions 34 and 44 are made of a binder resin in which conductive fillers are dispersed.

A plurality of solar cells 10 are, for example, arranged on the same plane and modularized by means of a first protection member 51 for covering the light receiving surface side, a second protection member 52 for covering the back surface side, and a encapsulant 53 provided between the first protection member 51 and the second protection member 52 (see FIG. 3). The plurality of solar cells 10 included in the solar cell module 50 are electrically connected to each other using a wiring member 54 which is a conductive member. A single wiring member 54 is, for example, connected to the light receiving surface electrode 12 of one of the adjacent solar cells 10 and to the back surface electrode 13 of the other one of the solar cells 10. In other words, the wiring member 54 connects the adjacent solar cells to each other in series.

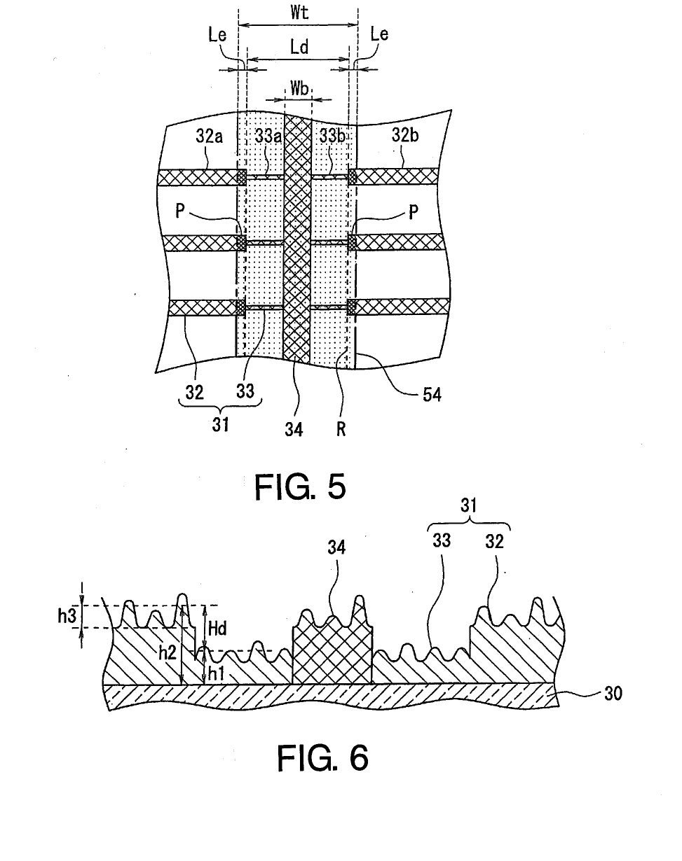

The structure near the bus bar portion 34 of the light receiving surface electrode 12 will be further described in detail by reference to FIG. 4 to FIG. 6. An explanation of the structure near the bus bar 44 of the back surface electrode 13 will be omitted because it is similar to the case of the light receiving surface electrode 12. FIG. 4 and FIG. 5 show an enlarged view of Part B in FIG. 1 and an enlarged view of Part C in FIG. 2, respectively, both showing the enlarged neighborhood of the bus bar portion 34. In FIG. 5, the position of the wiring member 54 is indicated by a two-dot chain line.

In the present embodiment, the finger portion 31 is configured to include the current collecting finger portion 32 and the connecting finger portion 33. On the light receiving surface, a separation region R extending in the direction intersecting with the current collecting finger portions 32 to separate the current collecting finger portions 32 (see FIG. 4). The separation region R is a region in which the current collecting finger portions 32 are not formed, and the current collecting finger portions 32 are formed on both sides of the separation region R with the separation region R therebetween. Then, in the separation region R, the bus bar portion 34 extending along the longitudinal direction of the separation region R and the connecting finger portions 33 for connecting between the current collecting finger portions 32 and the bus bar portions 34 are formed.

The current collecting finger portions 32 and the connecting finger portions 33 are formed, for example, on the same straight line orthogonal to the bus bar portion 34. One end of the connecting finger 33 is connected to the current collecting finger portion 32, and the other end is connected to the bus bar portion 34. That is, some of the carriers collected in the current collecting finger portions 32 are transported to the bus bar portion 34 via the connecting finger portion 33. The connecting finger portions 33 are formed so as to extend outward from both ends of the bus bar portion 34 in the width direction in a region near the bus bar portion 34.

The lengths of the connecting finger portions 33 are equal to each other (including when they can be considered to be substantially equal to each other, such as when a difference in the lengths is within 5%). That is, a pair of connecting finger portions 33a and 33b extending outward from both ends of the bus bar portion 34 in the width direction have equal lengths. It is then preferable to position the bus bar portion 34 in the center position between the pair of current collecting finger portions 32a and 32b (i.e. separation region R) connected to the bus bar portion 34 via the connecting finger portions 33a and 33b.

The connecting finger portion 33 is preferably formed within a range of approximately 2.0 mm from the end of the bus bar portion 34. In other words, the length Lf of the connecting finger portion 32 is preferably 2.0 mm or less. Although the length Lf is preferably changed according to the width Wb of the bus bar portion 34 and the width Wt of the wiring member 54, typically, a length is preferably from 0.1 mm to 1.0 mm, and more preferably, from 0.2 mm to 0.7 mm. In the present embodiment, {Lf×2+Wb} is equal to the distance Ld between the current collecting finger portions 32a and 32b (that is, the width of the separation region R).

The wiring member 54 is provided across the ends of the current collecting finger portions 32a and 32b located on both sides of the separation region R with the separation region R therebetween (see FIG. 5). In the present embodiment, the wiring member 54 is provided so as to cover the entire bus bar portion 34 along the longitudinal direction of the bus bar portion 34. The width Wt of the wiring member 54 is larger than the width Wb of the bus bar portion 34. The wiring member 54 protrudes from both ends of the bus bar portion 34 in the width direction and extends onto the current collecting finger portions 32a and 32b. That is, the distance Ld is set to be smaller than the width Wt. The width Wb of the bus bar portion 34 is preferably from 0.1 mm to 2.0 mm, and more preferably, from 0.5 mm to 1.5 mm. The width Wt of the wiring member 54 is preferably, for example, from 0.2 mm to 4.0 mm, and more preferably, from 1.0 mm to 2.0 mm, within a range that satisfies the condition Wt>Wb.

The connecting finger portions 33a and 33b are entirely covered by the wiring member 54. Regarding the current collecting finger portions 32a and 32b, only their ends on the separation region R side are covered by the wiring member 54. The wiring member 54 is located such that the center portion of the wiring member 54 in the width direction matches the center portion of the bus bar portion 34 in the width direction, and the lengths Le of the ends of the current collecting finger portions 32a and 32b covered by the wiring member 54 are preferably equal to each other. The length Le is preferably from 0.05 mm to 1.0 mm, and more preferably, 0.1 mm to 0.5 mm, in consideration of shortening of the current path and installation tolerance of the wiring member 54.

The height h1 of the connecting finger portion 33 is set to be lower than the height h2 of the end of the current collecting finger portion 32 on the separation region R side (see FIG. 6). Here, the heights h1 and h2 are defined as the heights from the surface of the transparent conductive layer 30 to the surfaces of the respective finger portions along the thickness direction. The heights h1 and h2 are averages of values measured by cross-section observation using a scanning electron microscope (SEM). It is preferable that the highest portion h1max of the connecting finger portion 33 is smaller than the height h2. In the present embodiment, the height of the current collecting finger portion 32 (average) is higher than the height h1 of the connecting finger portion 33 not only at the end of the current collecting finger portion 32 on the separation region R side but also in the entire current collecting finger portion 32. The height of the current collecting finger portion 32 (average) is equal throughout the current collecting finger portion 32. The height h2 will be hereinafter described as the height h2 of the collecting finger portion 32.

While contact between the wiring member 54 and the connecting finger portions 33 is prevented or suppressed by setting the height h1 to be lower than h2, the collecting finger portions 32 contact the wiring member 54. The ends of the current collecting finger portions 32a and 32b on the separation region R side contact the ends of the wiring member 54 in the width direction, respectively. Meanwhile, the portion near the middle portion of the wiring member 54, which is away from the both end portions of the wiring member 54 in the width direction, does not contact the finger portions 31. The contact portions between the wiring member 54 and the collecting finger portions 32 become collecting points P (see FIG. 5). The collecting points P are preferably provided on the respective current collecting finger portions 32. Carriers collected by the current collecting finger portion 32 are transported to the wiring member 54 through this collecting point P, thereby being extracted to the outside of the solar cell module 50.

The difference Hd in the heights (that is, h2−h1) between the current collecting finger portion 32 on which the collecting point P is provided and the connecting finger portion 33 is preferably made greater than the height h3 which is the surface irregularity of the current collecting finger portion 32. In particular, when the finger portions 31 are formed by screen printing, this structure is preferable because irregularity tends to be formed on the electrode surface. By making the height difference Hd greater than the surface irregularity height h3, it is possible to prevent the wiring member 54 from contacting the connecting finger portions 33 and enable the collecting points P to be arranged at the ends of the current collecting finger portions 32 on the separation region R side in a more reliable manner. Here, the height h3 of the surface irregularity is an average that can be calculated by three-dimensional measurement SEM.

More specifically, the height h2 of the current collecting finger portion 32 is preferably from 15 μm to 50 μm, and more preferably from 20 μm to 40 μm. The height h1 of the connecting finger portion 33 is preferably from 5 μm to 30 μm, and more preferably, from 10 μm mm to 20 μm, within a range that satisfies the condition height h2>height h1. For example, the height h1 is preferably set to be approximately ½ of the height h2. Adopting such heights h1 and h2 enables the collecting points P to be positioned at the ends of the current collecting finger portions 32 on the separation region R side in a more reliable manner.

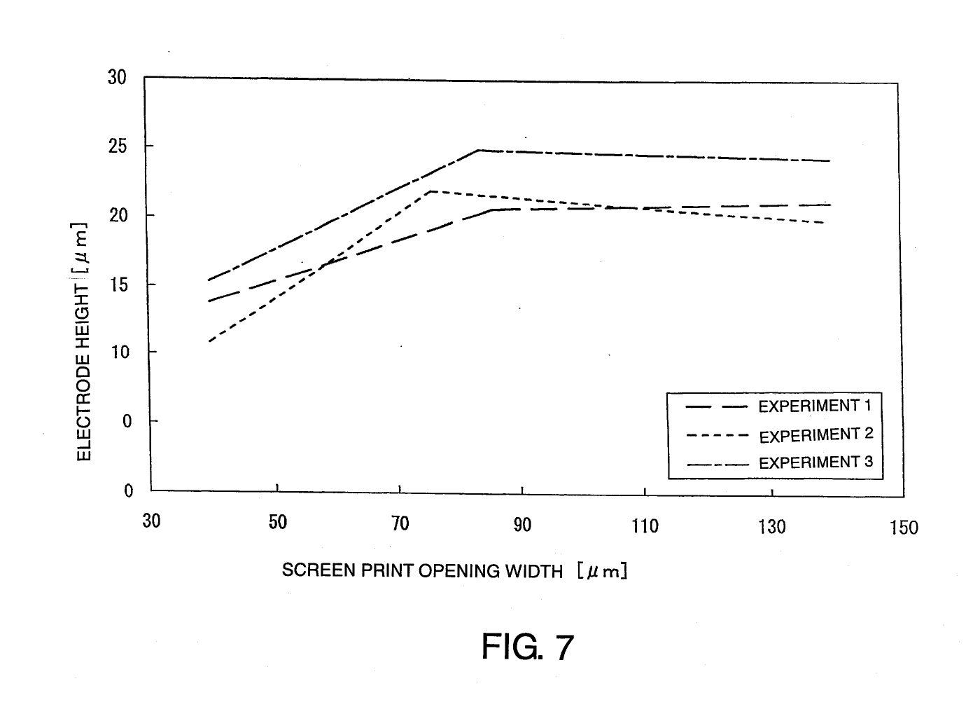

FIG. 7 shows the relationship between the electrode height (average) and the screen print opening width in the case where the finger portions 31 are formed by screen printing. FIG. 7 shows the results of Experiments 1 to 3. In reality, there is irregularity in the height of the electrode, as shown in FIG. 6. In Experiments 1 to 3,screen printing was performed using the same silver paste under the same conditions. From all the experiment results, the electrode height is constant if the screen print opening width is equal to or greater than a predetermined screen print opening width, while the electrode height is gradually lowered as the opening width becomes smaller if the screen print opening width becomes equal to or smaller than the predetermined screen print opening width.

By forming the line width of the connecting finger portion 33 so as to be smaller than that of the current collecting finger portion 32 based on the experiment results shown in FIG. 7, it is possible to form the current collecting finger portion 32 and the connecting finger portion 33 having different heights in a single screen printing operation. For example, if the connecting finger portion 33 having a height h1 of approximately 10 μm to 15 μm is formed, the line width of the connecting finger portion 33 is set to be approximately 40 μm to 50 μm, while if the current collecting finger portion 32 having a height h2 of approximately 20 μm to 25 μm is formed, the line width of the current collecting finger portion 32 is set to be approximately 90 μm or greater. The line width can be changed by the opening width of the screen print used in the screen printing. It is also possible to, for example, make the height h1 higher using a silver paste of high viscosity. Further, even without using screen printing, a portion of the electrode which is highest in the surrounding area (a portion which becomes a collecting point P) can be easily positioned at the end of the current collecting finger on the separation region R side by making the line width of the connecting finger portion smaller than that of the current collecting finger portion. This is because the highest portion of the electrode appears more frequently as the area of the electrode increases.

In the present embodiment, the height of the bus bar portion 34 is set to be equal to that of the current collecting finger portion 32, and the collecting points are also formed on the bus bar portions 34.

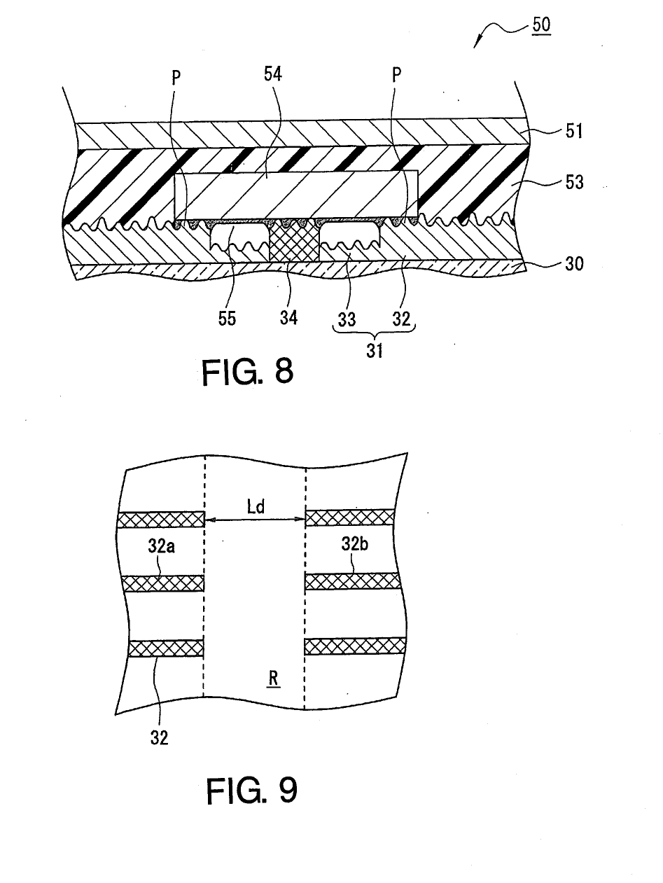

Next, the functions and the effects of the solar cell 10 and solar cell module 50 will be described in detail by reference to FIG. 8. FIG. 8 shows an enlarged view of the neighborhood of the bus bar portion 34 in the solar cell module 50.

In the solar cell module 50, the wiring member 54 is connected onto the bus bar portion 34 and the current collecting finger portion 32 using, for example, an adhesive 55. The adhesive 55 is a non-conductive adhesive or a conductive adhesive in which conductive fillers, such as silver, are dispersed in a resin. The wiring member 54 is thermally compressed to the current collecting finger portion 32, etc. with the film type adhesive 55 therebetween. In this thermal compression, convex portions on the surface of the current collecting finger portion 32, etc. are pressed by the wiring member 54 and compressed, and, for example, the wiring member 54 and those convex portions contact each other. The adhesive 55 mainly exists in concave portions on the electrode surface and strongly bond the wiring member 54 to the electrode. Thus, the collecting point P is formed.

Because, in the embodiment illustrated in FIG. 8, the height h1 of the connecting finger portion 33 is lower than the height h2 of the current collecting finger portion 32, the connecting finger portion 33 and the wiring member 54 do not contact each other, but the end of the current collecting finger portion 32 on the separation region R side and the end of the wiring member 54 contact each other, thereby forming the collecting point P. Thus, carriers are transported from the collecting point P at the end of the current collecting finger portion 32 to the end of the wiring member 54. Therefore, the current path between the light receiving surface electrode 12 and the wiring member 54 becomes shorter, thereby reducing resistance loss in a wiring part.

Further, if the collecting point P at the end of the current collecting finger portion 32 is lost due to, for example, an impact while in use, carriers collected in the current collecting finger portion 32 are transported to the bus bar portion 34 via the connecting finger portion 33 and extracted from the collecting point of the bus bar portion 34.

Further because a contact surface between the wiring member 54 and the electrode is small in the solar cell module 50, it is also possible to reduce pressure for thermal compression. Thus, it is possible to suppress cracks in the solar cell 10 during thermal compression, even if the thickness of the substrate 20 is thin.

The back surface electrode 13 can also achieve the same functions and effects if it is configured to have the same structure as the light receiving surface electrode 12.

The design of the above embodiment can be changed as desired within a scope without departing from the objective of the invention. FIG. 9 shows a variant of the above-described embodiment. In FIG. 9, the components that are the same as those included in the solar cell 10 are assigned the same numerals as in FIG. 4, and redundant descriptions will be omitted. In the embodiment illustrated in FIG. 9, the separation region R which intersects with the current collecting finger portion 32 is provided on the light receiving surface. The separation region R is orthogonal to, for example, the current collecting finger portion 32, thereby dividing the current collecting finger portion 32, and the current collecting finger portions 32 are formed on both sides of the separation region R with the separation region R therebetween. Although the embodiment illustrated in FIG. 9 is common with the solar cell 10 in the above points, it differs from the solar cell 10 in that the bus bar portions and the connecting finger portions are not formed in the separation region R, and that the current collecting finger portions 32 arranged on both sides of the separation region R with the separation region R therebetween are electrically separated from each other.

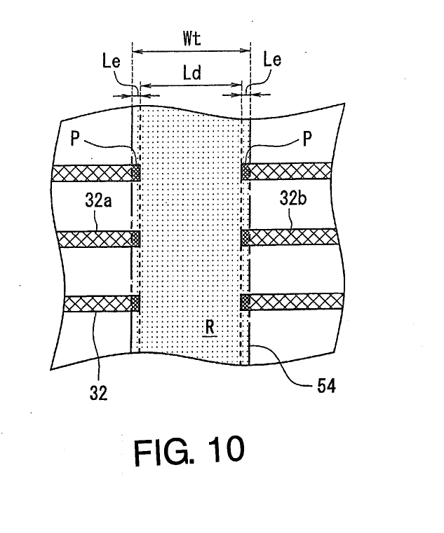

In FIG. 10, a position of the wiring member 54 is indicated by a two-dot chain line. The wiring member 54 is provided so as to cover the separation region R and extend across the ends of the current collecting finger portions 32 arranged on both sides of the separation region R with the separation region R therebetween. The distance Ld between the pair of current collecting finger portions 32a and 32b, which are formed on both sides of the separation region R along the same straight line in the width direction with the separation region R therebetween, are set to be slightly smaller than the width Wt of the wiring member 54. Then, the ends of the current collecting finger portions 32 on the separation region R side contact the ends of the wiring member 54, thereby forming the collecting points P. Such a structure can also achieve the same functions and effects as the above-described embodiment. Further, like the solar cell 10, a variant in which the connecting finger portions are formed in the separation region R, while the bus bar units are not formed may be adopted.

In other words, in both of the solar cell 10 and its variant, a plurality of current collecting finger portions 32, which intersect with the separation region R, are formed on both sides of the separation region R with the separation region R therebetween. Therefore, the ends of the plurality of current collecting finger portions 32 which are set as the collecting points are arranged along the separation region R, and it is possible to concentrate the collecting points on both sides of the separation region R. As such, with the solar cell 10 and its variant, it is possible to form the current path effectively and reduce output loss. In other words, it is possible to reduce variations in the collecting points, thereby increasing output.

1. A solar cell comprising:
current collecting finger portions formed on a main surface of a photoelectric conversion unit, wherein:
a separation region is formed on the main surface so as to extend in a direction intersecting with the current collecting finger portions to thereby separate the current collecting finger portions; and
the current collecting finger portions arranged on both sides of the separation region with the separation region therebetween are electrically separated from each other.

2. The solar cell according to claim 1, wherein:
a connecting finger portion for connecting the current collecting finger portions to each other is formed in the separation region; and
the height of the connecting finger portion is lower than that of ends of the current collecting finger portions on the separation region side.

3. The solar cell according to claim 2, wherein:
a bus bar portion extending in a direction intersecting with the connecting finger portion is formed in the separation region; and
the height of the bus bar portion is equal to that of the ends of the current collecting finger portions on the separation region side.

4. The solar cell according to claim 2, wherein a difference between the height of the current collecting finger portion on the separation region side and the height of the connecting finger portion is greater than the height of surface irregularity of the current collecting finger portions.

5. The solar cell according to claim 3, wherein a difference between the height of the current collecting finger portion on the separation region side and the height of the connecting finger portion is greater than the height of surface irregularity of the current collecting finger portions.

6. The solar cell according to claim 2, wherein the line width of the connecting finger is smaller than that of the ends of the collecting finger portions on the separation region side.

7. The solar cell according to claim 3, wherein the line width of the connecting finger is smaller than that of the ends of the collecting finger portions on the separation region side.

8. The solar cell according to claim 4, wherein the line width of the connecting finger is smaller than that of the ends of the collecting finger portions on the separation region side.

9. The solar cell according to claim 5, wherein the line width of the connecting finger is smaller than that of the ends of the collecting finger portions on the separation region side.

10. A solar cell module comprising:
a plurality of solar cell according to claim 1; and
a wiring member for connecting the solar cells to each other, wherein
the wiring member is provided across the ends of the current collecting finger portions arranged on both sides of the separation region with the separation region therebetween.

11. A solar cell module comprising:
a plurality of solar cell according to claim 2; and
a wiring member for connecting the solar cells to each other, wherein
the wiring member is provided across the ends of the current collecting finger portions arranged on both sides of the separation region with the separation region therebetween.

12. A solar cell module comprising:
a plurality of solar cell according to claim 3; and
a wiring member for connecting the solar cells to each other, wherein
the wiring member is provided across the ends of the current collecting finger portions arranged on both sides of the separation region with the separation region therebetween.

13. A solar cell module comprising:
a plurality of solar cell according to claim 4; and
a wiring member for connecting the solar cells to each other, wherein
the wiring member is provided across the ends of the current collecting finger portions arranged on both sides of the separation region with the separation region therebetween.

14. A solar cell module comprising:
a plurality of solar cell according to claim 5; and
a wiring member for connecting the solar cells to each other, wherein
the wiring member is provided across the ends of the current collecting finger portions arranged on both sides of the separation region with the separation region therebetween.

15. A solar cell module comprising:
a plurality of solar cell according to claim 6; and
a wiring member for connecting the solar cells to each other, wherein
the wiring member is provided across the ends of the current collecting finger portions arranged on both sides of the separation region with the separation region therebetween.

16. A solar cell module comprising:
a plurality of solar cell according to claim 7; and
a wiring member for connecting the solar cells to each other, wherein
the wiring member is provided across the ends of the current collecting finger portions arranged on both sides of the separation region with the separation region therebetween.

17. A solar cell module comprising:
a plurality of solar cell according to claim 8; and
a wiring member for connecting the solar cells to each other, wherein
the wiring member is provided across the ends of the current collecting finger portions arranged on both sides of the separation region with the separation region therebetween.

18. A solar cell module comprising:
a plurality of solar cell according to claim 9; and
a wiring member for connecting the solar cells to each other, wherein
the wiring member is provided across the ends of the current collecting finger portions arranged on both sides of the separation region with the separation region therebetween.

19. A method of manufacturing a solar cell, the method comprising the step of forming current collecting finger portions on a main surface of a photoelectric conversion unit by screen printing, wherein,
in the step, the current collecting finger portions are formed while a separation region, extending in a direction intersecting with the current collecting finger portions to separate the current collecting finger portions, remains on the main surface; and
the current collecting finger portions arranged on both sides of the separation region with the separation region therebetween are electrically separated.

20. The method according to claim 19, wherein:
in the step, a connecting finger portion for connecting the current collecting finger portions are formed; and
the line width of the connecting finger portion is made smaller than that of the current collecting finger portions, to thereby make the height of the connecting finger portion lower than that of the ends of the current collecting finger portions on the separation region side.
